(19) United States
(12) Patent Application Publication
(10) Pub. No.: US 2009/0252944 A1
(43) Pub. Date: Oct. 8, 2009

(54) SILICON WAFER AND PRODUCTION METHOD THEREOF

(75) Inventors: Kazunari KURITA, Tokyo (JP); Shuichi Omote, Tokyo (JP); Naoki Ikeda, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: SUMCO CORPORATION, Tokyo (JP)

(21) Appl. No.: 12/409,753

(22) Filed: Mar. 24, 2009

(30) Foreign Application Priority Data
Apr. 2, 2008 (JP) 2008-096053

(51) Int. Cl. B32B 5/00; H01L 21/322; C01B 33/02

(52) U.S. Cl. 428/220; 438/471; 423/348; 257/E21.318

(57) ABSTRACT

A silicon wafer is produced by subjecting a back face of a silicon wafer after the formation of a device structure to a given surface treatment so as to form a gettering sink layer having a good deflective strength.

### BACKGROUND OF THE INVENTION

1. Field of the Invention

This invention relates to a silicon wafer and a method of producing the same, and more particularly to a technique for producing a thin silicon wafer wherein the diffusion of heavy metal incorporated as an impurity into a device-forming region is suppressed while maintaining a good deflective strength in a second step of silicon wafer production after a first step of a semiconductor device process.

2. Description of the Related Art

With the advance of techniques for electronics such as mobile phones and digital still cameras, it is increasing to thin a semiconductor device package to be built in such electronics. In order to thin the package, it is necessary to thin a semiconductor device chip, and many thinned device chips at the present time.

A semiconductor device process is roughly divided into a first step of forming a device structure and a second step of conducting a backside grinding or the like. As a problem of the semiconductor device process is mentioned an incorporation of the heavy metal as an undesirable impurity into a silicon wafer. The incorporation of the heavy metal significantly produces a bad influence on the electric properties of the device, e.g. pause time failure, retention failure, junction leakage failure and dielectric breakdown of oxide film. Therefore, it is common to adopt a gettering method for suppressing the diffusion of heavy metal into a device-forming (active) region located at a front face side of a silicon wafer.

As the conventional gettering method are known a so-called IG method wherein micro-defects inside the silicon wafer are used as a gettering sink (capture region) and a so-called EG method wherein mechanical strain is given to a face (back face) opposite to a device-forming face of a wafer by a sand blasting method or the like or a polycrystalline silicon film is deposited thereon.

The aforementioned conventional gettering method mostly relates to the first step of the semiconductor device process (device-producing step), so that it is required to conduct a heat treatment at not lower than 600° C. for removing the diffused heavy metal. On the other hand, it is difficult to sufficiently remove the heavy metal in the second step because since the heat-treating temperature is about 300° C. at most.

As a method for suppressing the diffusion of the heavy metal into the wafer is mentioned a method wherein a work-affected layer (work strain layer) is formed on a back face of the wafer as a gettering sink layer as disclosed, for example, in JP-A-2005-311025 and JP-A-2005-72150. That is, the work-affected layer is retained on the back face of the wafer by controlling the grinding and abrasion on the back face of the wafer after slicing, and hence the gettering is carried out by using the residual work-affected layer as a gettering sink layer.

However, since the work-affected layer is formed by crystal defects such as dislocation and the like, there is a problem that as the thickness of the work-affected layer becomes large, brittle fracture is easily caused due to the presence of crystal defects to lower the deflective strength of the silicon wafer. For this end, it is required to remove the work-affected layer for maintaining a good deflective strength, but in this case it is impossible to suppress the diffusion of the heavy metal into the wafer in the second step.

Thus, there is found no case of producing a silicon wafer having a good deflective strength while suppressing the diffusion of the heavy metal into the wafer in the second step.

### SUMMARY OF THE INVENTION

It is, therefore, an object of the invention to provide a silicon wafer wherein which can effectively suppress the diffusion of the heavy metal from the back face of the silicon wafer into a device active region can be effectively suppressed while maintaining a good deflective strength by applying a given surface treatment to form a gettering sink layer in the second step of the semiconductor device process after the formation of the device structure, and a production method thereof.

In order to achieve the above object, the summary and construction of the invention are as follows.

(1) A method of producing a silicon wafer, which comprises subjecting a back face of a silicon wafer after the formation of a device structure to a given surface treatment so as to form a gettering sink layer having a good deflective strength.

(2) The method according to the item (1), wherein the given surface treatment comprises a step of grinding the back face of the silicon wafer up to a given wafer thickness to form a work-affected layer thereon and a step of conducting a polishing by a given polishing method to control the work-affected layer to a given thickness, and the work-affected layer having the given thickness is the gettering sink layer.

(3) The method according to the item (2), wherein the given thickness of the silicon wafer thinned by the grinding of the back face is not more than 100 μm.

(4) The method according to the item (2), wherein the given thickness of the work-affected layer is not more than 100 nm.

(5) The method according to the item (2), wherein the given abrasion method is chemical mechanical polishing or dry polishing.

(6) A silicon wafer produced by a method as described in any one of the items (1) to (5).

According to the invention, it is made possible to provide a silicon wafer wherein which can effectively suppress the diffusion of the heavy metal from the back face of the silicon wafer into a device active region can be effectively suppressed while maintaining a good deflective strength by applying a given surface treatment to form a gettering sink layer in the second step of the semiconductor device process after the formation of the device structure, and a production method thereof.

### BRIEF DESCRIPTION OF THE DRAWING

The invention will be described with reference to the accompanying drawings, wherein:

FIG. 1 is a flow chart illustrating steps for producing a silicon wafer by the production method according to the invention, wherein (a) is an image of rough grinding, (b) is an image of finish grinding and (c) is an image of polishing;

FIG. 2 is a photograph of a cross-section of a wafer obtained by the method of the invention as observed by means of TEM (transmission electron microscope), wherein (a) is a state before grinding, (b) is a state after rough grinding with a grinding stone of #360-#2000 and (c) is a state after finish grinding with a grinding stone of #24000 and subsequent dry polishing so as to control a thickness of a work-affected layer to 20 nm;

FIG. 3 is a photograph of a cross-section of the conventional silicon wafer as observed by means of TEM (transmission electron microscope) and shows a state after the work-affected layer is completely removed by chemical mechanical polishing; and

FIG. 4 is a flow chart illustrating cross-sectional change of a silicon wafer by grinding and polishing in Example 1 and Comparative Example 2, wherein (a) is a state before grinding, (b) is a state after rough grinding, (c) is a state after finish grinding, (d) is a state when a thickness of a work-affected layer is controlled by chemical mechanical polishing (Example 1) and (e) is a state when a work-affected layer is completely removed by chemical mechanical polishing (Comparative Example 2).

### DESCRIPTION OF THE PREFERRED EMBODIMENTS

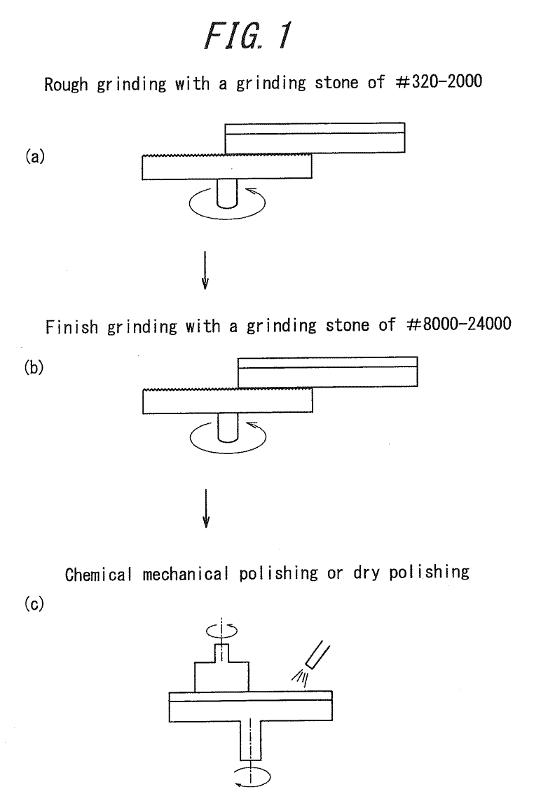

FIGS. 1(a)-(c) are a flow chart illustrating steps of producing a silicon wafer by the production method according to the invention.

In the method of producing a silicon wafer according to the invention, the back face of the silicon wafer after the formation of a device structure is subjected to a given surface treatment so as to form a gettering sink layer thereon in the second step of the semiconductor device process. The given surface treatment comprises a step of grinding the back face of the silicon wafer up to a given wafer thickness to form a work-affected layer thereon and a step of conducting a polishing by a given polishing method to control the work-affected layer to a given thickness, wherein the work-affected layer having the given thickness is preferable to be the gettering sink layer. In the second step of the conventional semiconductor device process, it is common to conduct grinding or polishing for thinning the silicon wafer to a given thickness, so that there is especially caused a risk that the silicon wafer is contaminated with heavy metal during the grinding. Also, it is known that a work-affected layer is generated on the back face of the wafer by grinding. In this connection, the work-affected layer has been completely removed by subsequent chemical mechanical polishing (CMP) or the like in the conventional technique. However, the inventors have made various studies and found that the work-affected layer can be acted as a gettering layer for heavy metal by controlling the thickness of the work-affected layer so as to positively leave the work-affected layer and also that the deflective strength can be maintained without deterioration when the work-affected layer has a certain level of thickness, and as a result, the invention has been accomplished.

A typical example of the production method when the work-affected layer is used as a gettering sink layer will be described below.

The first step may be conducted according to a usual manner. As the subsequent second step is first conducted a back grinding. In the back grinding step, the back face of the wafer having, for example, a thickness of 750 μm is subjected to a rough grinding with a grinding stone of #320-#2000 to a thickness of about 100-120 μm as shown in FIG. 1(a), and then subjected to a finish grinding with grindstones of #8000-#24000 to a given wafer thickness, preferably to not more than 100 μm as shown in FIG. 1(b). The thickness of the silicon wafer exceeding 100 μm at the termination of the grinding step is not preferable in view of the thinning of the wafer because a package thickness of a device chip cannot be designed to be not more than 1 mm.

In the invention, the work-affected layer is formed by the above back grinding. Thereafter, the resulting work-affected layer is polished to a given thickness, preferably not more than 100 nm, more preferably not more than 70 nm by chemical mechanical polishing (CMP) or dry polishing as shown in FIG. 1(c). The reason why the thickness of the work-affected layer is limited to the above value is due to the fact that since the work-affected layer is formed by crystal defects such as dislocation or the like, as the thickness of the work-affected layer becomes large, brittle fracture is easily caused due to the presence of crystal defects and hence the sufficient deflective strength can not be maintained.

By the above grinding and polishing is formed the work-affected layer having a given thickness on the back face of the silicon wafer, which can capture the heavy metal generated in the second step while maintaining the good deflective strength.

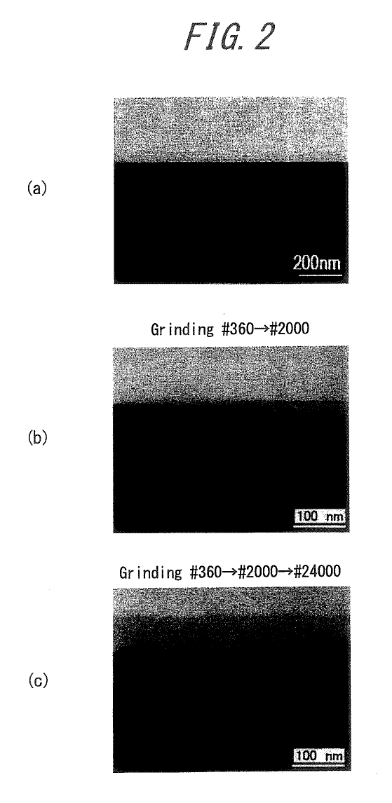

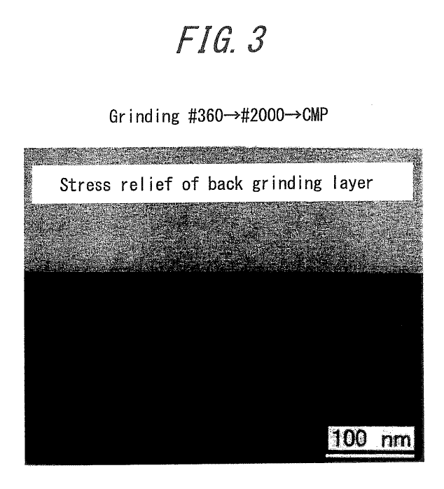

FIGS. 2(a)-2(c) are photographs illustrating an example in a cross sectional change of a silicon wafer observed by means of a transmission electron microscope (TEM) when a work-affected layer having a given thickness is formed on the back face of the silicon wafer by grinding and polishing according to the method of the invention, respectively. FIG. 2(a) is a cross-sectional view of a silicon wafer before the grinding of the back face, and FIG. 2(b) is a cross-sectional view of the silicon wafer after the rough grinding with grindstones of #360-#2000, and FIG. 2(c) is a cross-sectional view of the silicon wafer after the finish grinding with grindstones of #24000 and the subsequent dry polishing so as to adjust the thickness of the work-affected layer to 20 nm. Also, FIG. 3 is a cross-sectional view of the conventional silicon wafer wherein the work-affected layer is completely removed by chemical mechanical polishing after the rough grinding with a grinding stone of #360-#2000.

Although the above is merely described with respect to one embodiment of the invention, various modifications may be made without departing from the scope of the appended claims. According to the invention, the work-affected layer is let to form a gettering sink layer by controlling grinding and polishing methods, but a film having the same structure as the work-affected layer may be formed, for example, on the back face of the wafer by another surface treatment such as chemical vapor deposition or the like.

### EXAMPLE 1

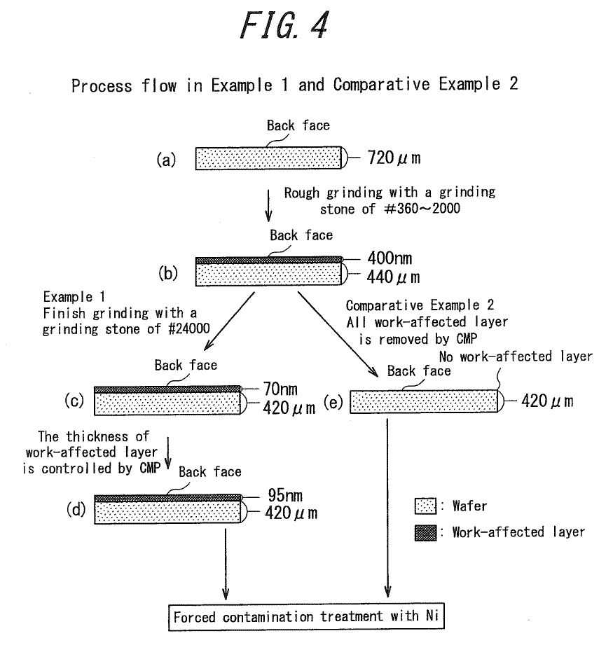

A back face of a silicon wafer having a thickness of 720 μm is roughly ground with grindstones of #360 and then of #2000 in a back grinding apparatus (FIG. 4(a)). After the rough grinding, the thickness of the silicon wafer is 440 μm and the thickness of a work-affected layer is 400 nm (FIG. 4(b)). Next, finish grinding is conducted with grindstones of #24000. After the finish grinding, the thickness of the silicon wafer is 420 μm and the thickness of the work-affected layer is 70 nm (FIG. 4(c)). Then, the work-affected layer is polished to a thickness of 95 nm by dry polishing (FIG. 4(d)).

### EXAMPLE 2

The work-affected layer is polished to a thickness of 87 nm by dry polishing. The other steps are the same as in Example 1.

### EXAMPLE 3

The work-affected layer is polished to a thickness of 70 nm by dry polishing. The other steps are the same as in Example 1.

### EXAMPLE 4

The work-affected layer is polished to a thickness of 20 nm by dry polishing. The other steps are the same as in Example 1.

### COMPARATIVE EXAMPLE 1

The work-affected layer is polished to a thickness of 200 nm by dry polishing. The other steps are the same as in Example 1.

### COMPARATIVE EXAMPLE 2

The work-affected layer is completely removed by chemical mechanical polishing (CMP). The other steps are the same as in Example 1.

Evaluation Method

Each of the silicon wafers prepared for evaluation is subjected to a forced contamination treatment by applying a Ni contamination solution onto the surface of the wafer at 1×10¹² atoms/cm² through a spin coat method and then charging into a heat-treating furnace to conduct a diffusion heat treatment in a nitrogen atmosphere at 900° C. for 30 minutes. Then, each sample wafer in Examples 1-4 and Comparative Examples 1 and 2 is subjected to a light etching and thereafter shallow pits on the back face of the wafer are observed by means of an optical microscope to evaluate the presence or absence of gettering ability in the work-affected layer. Also, the deflective strength on the thickness of the work-affected layer is measured and evaluated.

Moreover, the presence or absence of the gettering ability can be confirmed by shallow pits generated in the work-affected layer on the back face of the wafer. The shallow pit is a microscopic pit generated mainly due to metallic contamination when the surface of the wafer is selectively etched. When many shallow pits are existent in the work-affected layer, it is considered that these pits serve as a gettering sink capturing heavy metal(s) diffused in the wafer.

In addition, the deflective strength of the silicon wafer is measured by a three-point bending measurement. The measuring conditions when using a commercially available precision universal testing machine are a breaking load of less than 20 kgf, a testing speed of not lower than 0.05 mm/min but not higher than 500 mm/min, and a braking stress of not more than 500 Mpa.

The evaluation results are shown in Table 1.

TABLE 1

| | | | | | Comparative | |
|---|---|---|---|---|---|---|
| | Example | | | | Example | |
| | 1 | 2 | 3 | 4 | 1 | 2 |
| Thickness of | 95 | 87 | 70 | 20 | 200 | 0 |
| work-affected | | | | | | |
| layer (nm) | | | | | | |
| Gettering | Present | Present | Present | Present | Present | Absent |
| ability | | | | | | |
| Deflective | 600 | 800 | 1200 | 1480 | 400 | 1500 |
| strength (MPa) | | | | | | |

As seen from the results of Table 1, in Examples 1-4 and Comparative Example 1, the gettering ability is present and the work-affected layer serves as a gettering sink. In Comparative Example 2, almost of Ni are present in the bulk of the wafer since there is no gettering sink layer in the wafer. Also, the deflective strength becomes high as the thickness of the work-affected layer becomes thin. The deflective strength required for a silicon wafer having a thickness of 420 μm is not less than 500 Mpa, which is satisfied in all of Examples 1-4. As the gettering ability and deflective strength are also evaluated when the thickness of the work-affected layer is adjusted to 100 nm by chemical mechanical polishing instead of dry polishing, the same effect as in the case of dry polishing is obtained.

According to the invention, it is made possible to provide a silicon wafer wherein which can effectively suppress the diffusion of the heavy metal from the back face of the silicon wafer into a device active region can be effectively suppressed while maintaining a good deflective strength by applying a given surface treatment to form a gettering sink layer in the second step of the semiconductor device process after the formation of the device structure, and a production method thereof.

1. A method of producing a silicon wafer, which comprises subjecting a back face of a silicon wafer after the formation of a device structure to a given surface treatment so as to form a gettering sink layer having a good deflective strength.

2. The method according to claim 1, wherein the given surface treatment comprises a step of grinding the back face of the silicon wafer up to a given wafer thickness to form a work-affected layer thereon and a step of conducting a polishing by a given polishing method to control the work-affected layer to a given thickness, and the work-affected layer having the given thickness is the gettering sink layer.

3. The method according to claim 2, wherein the given thickness of the silicon wafer thinned by the grinding of the back face is not more than 100 μm.

4. The method according to claim 2, wherein the given thickness of the work-affected layer is not more than 100 nm.

5. The method according to claim 2, wherein the given abrasion method is chemical mechanical polishing or dry polishing.

6. A silicon wafer produced by a method as claimed in claim 1.

7. A silicon wafer produced by a method as claimed in claim 2.

8. A silicon wafer produced by a method as claimed in claim 3.

9. A silicon wafer produced by a method as claimed in claim 4.

10. A silicon wafer produced by a method as claimed in claim 5.
